(19) United States
(12) Patent Application Publication
(10) Pub. No.: US 2023/0341155 A1
(43) Pub. Date: Oct. 26, 2023

(54) PRECURSOR VESSEL COOLING ASSEMBLY, SYSTEM INCLUDING THE ASSEMBLY, AND METHODS OF USING SAME

(71) Applicant: ASM IP Holding B.V., Almere (NL)

(72) Inventors: Pawan Sharma, Tempe, AZ (US); Aadil Vora, Tempe, AZ (US); Ankit Kimtee, Phoenix, AZ (US)

(21) Appl. No.: 18/135,792

(22) Filed: Apr. 18, 2023

Related U.S. Application Data
(60) Provisional application No. 63/333,412, filed on Apr. 21, 2022.

(51) Int. Cl. F25B 21/02; F25B 41/40

(52) U.S. Cl. CPC F25B 21/02; F25B 41/40; F25B 2321/021; F25B 2321/023; F25B 2700/21

(57) ABSTRACT

A precursor vessel cooling assembly, a reactor system including the assembly, and methods of using the assembly and system are disclosed. The precursor vessel cooling assembly includes a thermoelectric cooling device and a fluid-cooled plate to maintain a desired temperature of a precursor vessel or other portion of the precursor vessel cooling assembly.

### CROSS-REFERENCE TO RELATED APPLICATIONS

This application is a nonprovisional of, and claims priority to and the benefit of, U.S. Provisional Patent Application No. 63/333,412, filed Apr. 21, 2022 and entitled “PRECURSOR VESSEL COOLING ASSEMBLY, SYSTEM INCLUDING THE ASSEMBLY, AND METHODS OF USING SAME,” which is hereby incorporated by reference herein.

### FIELD OF INVENTION

The present disclosure generally relates to an apparatus and methods for use in gas-phase reactor systems. More particularly, the disclosure relates to assemblies for cooling a precursor vessel, to systems including the assemblies, and to methods of using the assemblies and systems.

### BACKGROUND OF THE DISCLOSURE

Gas-phase reactor systems, such as chemical vapor deposition (CVD), plasma-enhanced CVD (PECVD), atomic layer deposition (ALD), and the like reactor systems can be used for a variety of applications, including depositing and etching materials on a substrate surface. For example, gas-phase reactor systems can be used to deposit and/or etch layers on a substrate to form electronic devices, such as semiconductor devices, flat panel display devices, photovoltaic devices, microelectromechanical systems (MEMS), and the like.

A typical gas-phase reactor system includes a reactor including a reaction chamber, one or more precursor gas sources fluidly coupled to the reaction chamber, a gas distribution system to deliver gases to a surface of a substrate, and an exhaust source fluidly coupled to the reaction chamber.

A precursor gas source can include a vessel and a precursor that is a gas, liquid, or solid form at normal temperature and pressure (NTP). In many applications, particularly when the precursor is a liquid or solid, it is desirable to control a temperature of a vessel containing the precursor. For example, in some cases, it may be desirable to control a temperature of the vessel to a temperature below room temperature.

While systems exist for cooling a precursor within a vessel, such systems may be relatively inefficient and/or may not provide desired temperature control. Accordingly, improved precursor vessel cooling assemblies, reactor systems including the assemblies, and methods of using the assemblies and systems are desired.

Any discussion of problems and solutions set forth in this section has been included in this disclosure solely for the purpose of providing a context for the present disclosure, and should not be taken as an admission that any or all of the discussion was known at the time the invention was made.

### SUMMARY OF THE DISCLOSURE

Exemplary embodiments of this disclosure provide methods and an apparatus for cooling a precursor vessel suitable for use with or in a reactor system. While the ways in which various embodiments of the present disclosure address drawbacks of prior assemblies, methods and systems are discussed in more detail below, in general, various embodiments of the disclosure provide precursor vessel cooling assemblies that can provide desired vessel cooling and temperature control and/or increased lifetime of the assemblies.

In accordance with embodiments of the disclosure, a precursor vessel cooling assembly is provided. An exemplary precursor vessel cooling assembly includes a precursor vessel, a thermoelectric cooling device, and a fluid-cooled plate. The thermoelectric cooling device can include a first surface and a second surface. The first surface can be in thermal contact with a surface of the precursor vessel. The second surface can be in thermal contact with the fluid-cooled plate. The fluid-cooled plate can include a conduit, which can include a cooling fluid therein. The assembly can further include a pump to circulate the cooling fluid through the conduit. Exemplary systems can further include a heat exchanger to cool the cooling fluid. Exemplary assemblies can also include a first cooling fluid line coupled between the fluid-cooled plate and the heat exchanger. Exemplary precursor vessel cooling assemblies can also include a controller to control, for example, the heat exchanger and/or the thermoelectric cooling device. Exemplary precursor vessel assemblies can include a housing. The housing can encase the precursor vessel and the thermoelectric cooling device. The heat exchanger and/or the pump can be exterior of the housing.

In accordance with additional examples of the disclosure, a method is provided. Exemplary methods include cooling a precursor within a precursor vessel by providing a precursor vessel containing a precursor therein, cooling the precursor within the precursor vessel using a thermoelectric cooling device, and using a fluid-cooled plate in thermal contact with the thermoelectric cooling device, removing heat from the thermoelectric cooling device. The step of removing heat can include circulating a cooling fluid within the fluid-cooled plate. Exemplary methods can also include measuring a temperature of the precursor and controlling current through the thermoelectric cooling device based on the measured temperature and/or controlling a heat exchanger used to cool the cooling fluid.

In accordance with yet additional examples of the disclosure, a reactor system is provided. An exemplary reactor system includes a reaction chamber and a precursor delivery system coupled to the reaction chamber. The precursor delivery system can include a precursor vessel cooling assembly as described herein. The reactor system can additionally include a controller and/or a vacuum source.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system in accordance with at least one embodiment of the disclosure.

FIG. 2 illustrates a precursor vessel cooling assembly in accordance with at least one embodiment of the disclosure.

FIG. 3 illustrates a fluid-cooled plate in accordance with at least one embodiment of the disclosure.

FIG. 4 illustrates a heat exchanger in accordance with at least one embodiment of the disclosure.

FIG. 5 illustrates another view of a heat exchanger in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to an apparatus for cooling a precursor, to systems including such apparatus, and to methods of using the apparatus and systems. As described in more detail below, exemplary apparatus (e.g., assemblies) can be used to efficiently remove heat from a precursor vessel using a thermoelectric device, while maintaining efficiency and/or longevity of the thermoelectric device.

Exemplary precursor vessel cooling assemblies, reactor systems, and methods discussed herein can be used for a variety of applications. For example, the vessel cooling assemblies and reactor systems can be used for chemical vapor deposition (CVD) and/or (e.g., thermal) atomic layer deposition (ALD) processes.

CVD includes forming thin films of materials on substrates using reactant vapors (including “precursor gases”) of different reactant chemicals that are delivered to one or more substrates in a reaction chamber. In many cases, the reaction chamber includes only a single substrate supported on a substrate holder (such as a susceptor), with the substrate and substrate holder being maintained at a desired process temperature. In typical CVD processes, reactive reactant vapors react with one another to form thin films on the substrate, with the growth rate being related to the temperature and the amounts of reactant gases. In some cases, energy to drive the deposition process is supplied in part by plasma, e.g., by a remote or direct plasma process.

In some applications, the reactant gases are stored in gaseous form in a reactant source vessel. In such applications, the reactants are often gaseous at normal temperature and pressure. Examples of such gases include nitrogen, oxygen, hydrogen, and ammonia. However, in some cases, the vapors of source chemicals or precursors that are liquid or solid (e.g., hafnium chloride, hafnium oxide, zirconium dioxide, or the like) at normal temperature and pressure are used.

ALD is another process for forming thin films on substrates. In many applications, ALD uses a solid and/or liquid source chemical as described above. ALD is a type of vapor deposition wherein a film is built up through, e.g., self-saturating reactions performed in cycles. A thickness of an ALD-deposited film can be determined by the number of ALD cycles performed. In an ALD process, gaseous reactants are supplied, alternatingly and/or repeatedly, to the substrate to form a thin film of material on the substrate. One reactant can be absorbed in a self-limiting process on the substrate. A different, subsequently pulsed reactant reacts with the adsorbed material to form a single molecular layer of the desired material. Decomposition may occur through mutual reaction between the adsorbed species and with an appropriately selected reactant, such as in a ligand exchange or a gettering reaction. In a theoretical ALD reaction, no more than a molecular monolayer forms per cycle. Thicker films are produced through repeated growth cycles until the target thickness is achieved.

In theoretical ALD reactions, mutually reactive reactants are kept separate in the vapor phase with intervening removal processes between substrate exposures to the different reactants. For example, in time-divided ALD processes, reactants are provided in pulses to a stationary substrate, typically separated by purging or pump down phases; in space-divided ALD processes, a substrate is moved through zones with different reactants; and in some processes, aspects of both space-divided and time-divided ALD can be combined. Variants or hybrid processes of ALD and CVD allow some amount of CVD-like reactions, either through selection of the deposition conditions outside the normal ALD parameter windows and/or through allowing some amount of overlap between mutually reactive reactants during exposure to the substrate.

In this disclosure, an assembly may include a (e.g., solid or liquid) precursor vessel, a thermoelectric cooling device, and a fluid-cooled plate. The assemblies can include additional elements, such as heaters, temperature measurement devices, other components noted herein, and the like.

As used herein, a precursor source includes a vessel and a precursor therein. The terms precursor and reactant can be used interchangeably.

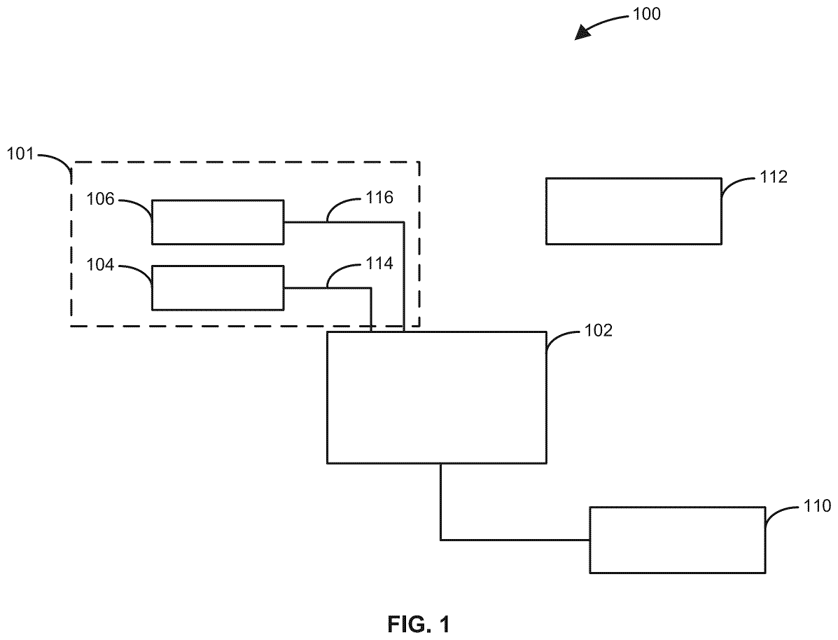

Turning now to the figures, FIG. 1 illustrates a reactor system 100 according to examples of the disclosure. The reactor system 100 can be used for, for example, CVD, ALD, other deposition processes, or the like. As noted above, such processes can be used during the formation of electronic devices, such as semiconductor devices.

In the illustrated example, the reactor system 100 includes one or more reaction chambers 102, a precursor injector system 101, a first precursor vessel 104, a second precursor vessel 106, an exhaust source 110, and a controller 112. The reactor system 100 can include one or more additional gas sources (not shown), such as an inert gas source, a carrier gas source, a purge gas source and/or another reactant source.

The reaction chamber 102 can include any suitable reaction chamber, such as an ALD or CVD reaction chamber. By way of example, the reaction chamber 102 includes a chamber suitable for a cyclical deposition process, such as an ALD process.

The precursor vessels 104 and 106 can be coupled to the reaction chamber 102 via input lines 114 and 116, which can each include flow controllers, valves, heaters, and the like. In some cases, the line 114 and/or 116 may be heated.

The exhaust source 110 can include one or more vacuum pumps.

The controller 112 includes electronic circuitry and software to selectively operate valves, manifolds, heaters, pumps and other components included in the reactor system 100. Such circuitry and components operate to introduce precursors, other optional reactants and purge gases from the respective sources (e.g., the precursor vessels 104, 106). The controller 112 can control timing of gas pulse sequences, temperature of the substrate and/or reaction chamber 102, pressure within the reaction chamber 102, and various other operations to provide proper operation of the reactor system 100, such as parameters of a precursor vessel cooling assembly as described herein.

The controller 112 can include control software to electrically or pneumatically control valves to control flow of precursors, reactants and purge gases into and out of the reaction chamber 102. The controller 112 can include modules, such as a software or hardware component, which performs certain tasks. A module may be configured to reside on the addressable storage medium of the control system and be configured to execute one or more processes.

Other configurations of the reactor system 100 are possible, including different numbers and kinds of precursor sources and vessels. Further, it will be appreciated that there are many arrangements of valves, conduits, precursor vessels, and auxiliary reactant sources that may be used to accomplish the goal of selectively and in a coordinated manner feeding gases into the reaction chamber 202. Further, as a schematic representation of a deposition assembly, many components have been omitted for simplicity of illustration, and such components may include, for example, various valves, manifolds, purifiers, heaters, containers, vents, and/or bypasses.

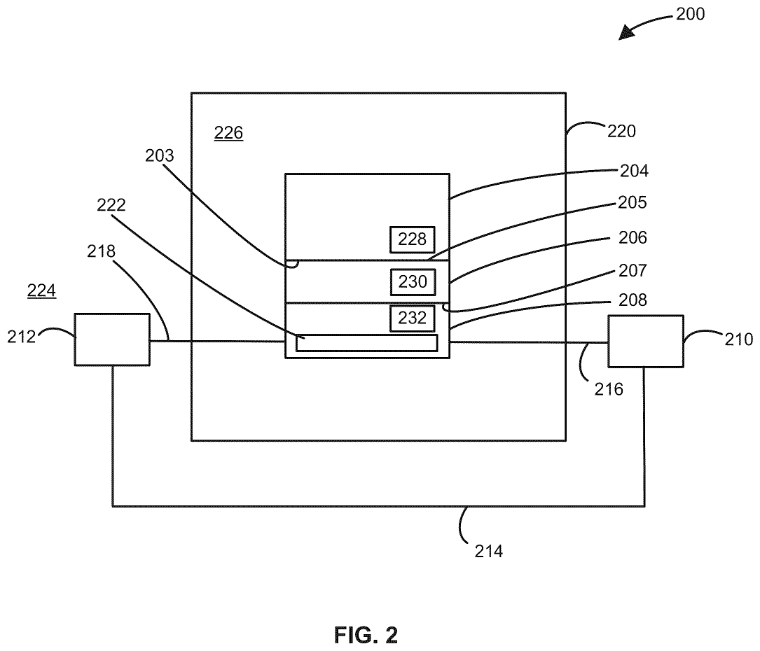

FIG. 2 illustrates a precursor vessel cooling assembly 200 in accordance with examples of the disclosure. The precursor vessel cooling assembly 200 can be used in a variety of applications and/or can be used in connection with the reactor system 100, described above.

In the illustrated example, the precursor vessel cooling assembly 200 includes a precursor vessel 204, a thermoelectric cooling device 206, and a fluid-cooled plate 208. The precursor vessel cooling assembly 200 can additionally include a pump 210, a heat exchanger 212, and one or more of flow lines 214, 216, and 218. The precursor vessel cooling assembly 200 is configured to efficiently remove heat from the precursor vessel 204, while maintaining longevity of assembly 200 and components thereof (e.g., the thermoelectric cooling device 206).

The precursor vessel 204 can be formed of any suitable material. By way of examples, the precursor vessel 204 can be formed of stainless steel. In other embodiments, the precursor vessel 204 or components thereof can be formed of high nickel alloys, aluminum, or titanium. It should be understood that the precursor vessel 204 or components thereof can be formed of any other material sufficient to allow sufficient thermal heat transfer to a precursor disposed within the precursor vessel 204, while being inert or not reacting with the precursor or contents within the precursor vessel 204 to any appreciable extent.

The thermoelectric cooling device 206 can include any suitable device that can cool a surface of the precursor vessel 204 upon application of power to the device. By way of example, the thermoelectric cooling device 206 can be or include a Peltier device. In accordance with examples of the disclosure, the thermoelectric cooling device 206 and/or the precursor vessel cooling assembly 200 is configured to cool the precursor vessel 204 from about 0° C. to about 20° C. below ambient temperature. The controller 112 can be used to control power to or of the thermoelectric cooling device 206 to maintain a desired temperature of the precursor vessel 204.

The thermoelectric cooling device 206 includes a first surface 205 and a second surface 207. The first surface 205 is in (e.g., direct) thermal contact with a surface 203 of the precursor vessel 204. The second surface 207 is in (e.g., direct) thermal contact with the fluid-cooled plate 208. During operation, upon application of power to the thermoelectric cooling device 206, the first surface 205 is cooled, and heat is produced at the second surface 207.

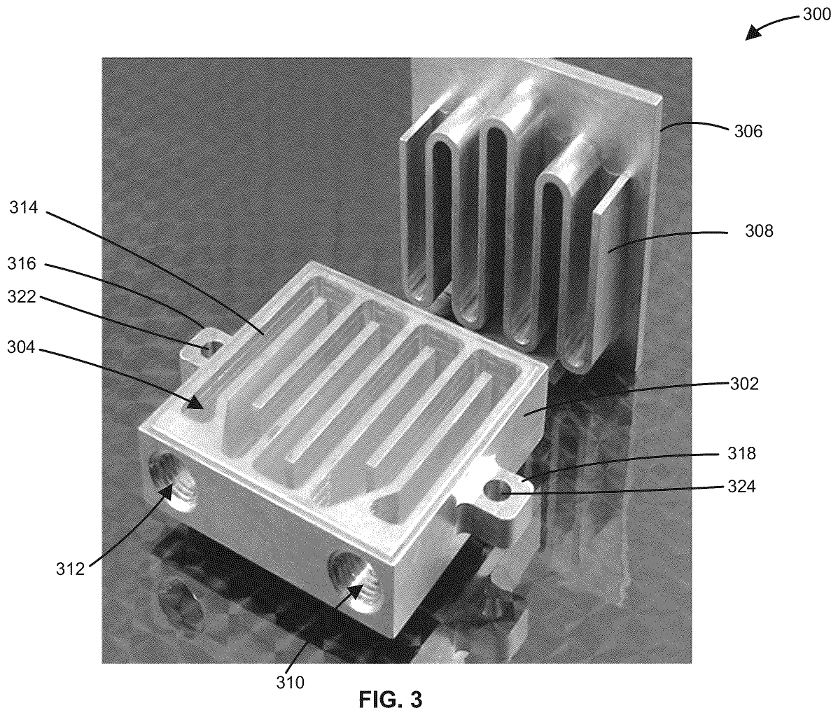

The fluid-cooled plate 208 can be used to remove heat from the second surface 207. FIG. 3 illustrates an exemplary fluid-cooled plate 300 suitable for use as fluid-cooled plate 208.

The fluid-cooled plate 300 can be formed of any suitable material, such as copper, aluminum, stainless steel, or the like. As illustrated in FIG. 3, the fluid-cooled plate 300 includes a body 302, including a conduit 304 formed therein. The conduit 304 includes an inlet 310, an outlet 312. The conduit 304 forms a path 314 that connects the inlet 310 to the outlet 312. In the illustrated example, the path 314 includes a serpentine path. However, in other embodiments, the path 314 may be any suitable shape and/or length. The body 302 can further include protrusions 316, 318, having apertures 322, 324 therein to allow removable attachment of the body 302 to another device, such as the precursor vessel 204 and/or the thermoelectric cooling device 206.

The fluid-cooled plate 300 can also include a lid 306. The lid 306 can suitably be formed of the same material as the body 302. As illustrated, the lid 306 can include a ridge 308, which substantially matches and can be inserted within the conduit 304. The ridge 308 may facilitate heat transfer to the lid 306 from the cooling fluid (e.g., cooling fluid 222, illustrated in FIG. 2) therein, and vice versa. The lid 306 and the body 302 can be suitably sealed together.

With reference again to FIG. 2, the pump 210 can include any suitable pump to cause circulation of a cooling fluid through the fluid-cooled plate 208/300 and the conduit 304. By way of example, the pump 210 can include a submersible or centrifugal-type pump. The pump 210 can be controlled using a controller, such as controller 112, to manipulate a flowrate of the cooling fluid to further facilitate desired temperature control of the precursor vessel 204.

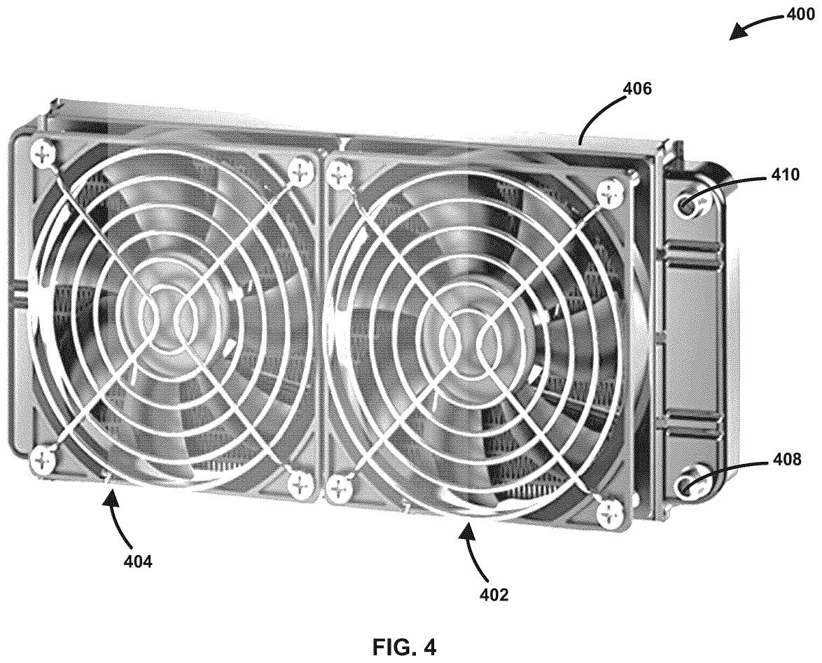

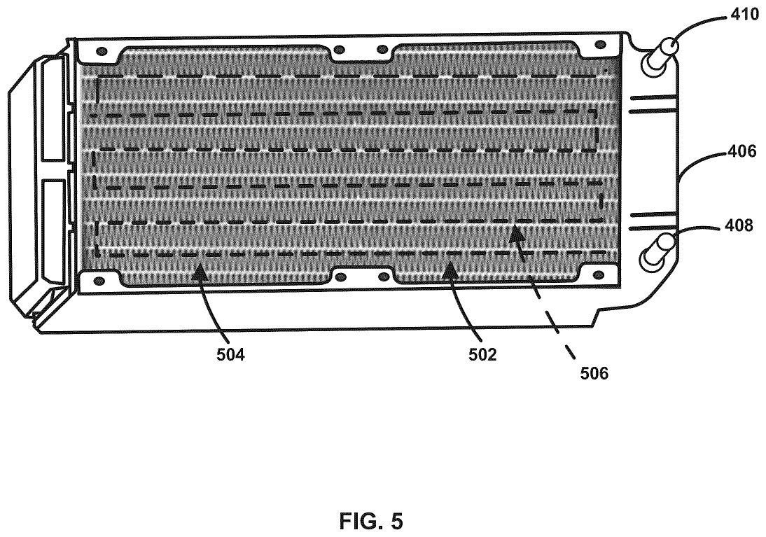

The heat exchanger 212 can include any suitable heat exchange device. By way of example, the heat exchanger 212 can be or include a radiator 400 as illustrated in FIGS. 4 and 5. The heat exchanger 212 can be fluidly coupled to the fluid-cooled plate 208 via a first cooling fluid line 218 coupled between the fluid-cooled plate 208 and the heat exchanger 212.

The radiator 400 can include one or more fans 402, 404 and a core 406. The fans 402, 404 can include any suitable axial and centrifugal fan. In accordance with examples of the disclosure, one or more of fans 402, 404 include a variable-speed fan, which can be controlled using a controller, such as the controller 112.

The core 406, further illustrated in FIG. 5, can include a cooling fluid inlet 408, a cooling fluid outlet 410, a cooling fluid channel 506, and fins 502. The fins 502 can be located on an outer surface 504 of the core 406 and/or the heat exchanger 400 and can be configured to facilitate heat transfer from the cooling fluid to an ambient environment by increasing available surface area for the heat transfer on the cooling fluid channel. The fins 502 can include an accordion shape, as illustrated. Alternatively, the fins 502 can include a protrusion-shape (e.g., rod, rectangle, or the like) or any other suitable shape.

The inlet 408 receives cooling fluid from fluid-cooled plate 208. The outlet 410 can be fluidly coupled to the pump 210, such that cooled cooling fluid circulates from the heat exchanger 212 to the pump 210.

The heat exchanger 212 cools the cooling fluid by dissipating the heat to an ambient environment 224. As illustrated in FIG. 2, ambient environment 224 may suitably be exterior a housing 220, which encases the precursor vessel 204, the thermoelectric cooling device 206, and the fluid-cooled plate 208. Thus, an environment 226 within the housing 220 can be kept relatively cool.

The precursor vessel cooling assembly 200 can include one or more temperature measurement devices 228, 230, 232, such as a thermocouple. In the illustrated example, the temperature measurement device 228 measures a temperature on or within the precursor vessel 204, the temperature measurement device 230 measures a temperature on or within the thermoelectric cooling device 206, and the temperature measurement device 232 measures a temperature on or within the fluid-cooled plate 208.

Measured temperature information from one or more temperature measurement devices (e.g., temperature measurement devices 228-232) can be sent to a controller, such as controller 112. The controller 112 or another controller can then adjust one or more parameters based on the measured temperature(s). For example, the controller (e.g., controller 112) can receive an input corresponding to a temperature of a precursor within the precursor vessel 204 and provide an output to the pump 210 to adjust a flowrate of a cooling fluid. Additionally or alternatively, the controller (e.g., controller 112) can receive an input corresponding to a temperature of the precursor within the vessel 204 and provide an output to the thermoelectric cooling device 206 to adjust a current through the thermoelectric cooling device 206. Additionally or alternatively, the controller (e.g., controller 112) can receive an input corresponding to a temperature of a precursor and provide an output to control a speed of a fan (e.g., fan 402 and/or fan 404). Other temperature measurements using temperature measurement devices 228-232 can be used to provide input to a controller, such as controller 112, the control pump 210, the thermoelectric cooling device 206, and/or the heat exchanger 212 as described herein.

In accordance with further exemplary embodiments of the disclosure, a method of cooling a precursor within a precursor vessel includes the steps of providing a precursor vessel containing a precursor therein; cooling the precursor within the precursor vessel using a thermoelectric cooling device comprising a first surface and a second surface, the first surface in thermal contact with a surface of the precursor vessel; and using a fluid-cooled plate in thermal contact with the second surface, removing heat from the thermoelectric cooling device. The precursor vessel, thermoelectric cooling device, and fluid-cooled plate, as well as other assembly and system components suitable for use with the exemplary methods, can be as described above.

In accordance with examples of these embodiments, the step of removing heat includes circulating a cooling fluid (e.g., water) within the fluid-cooled plate. The circulation can be performed using a pump, such as the pump 210. Exemplary methods can further include using a heat exchanger to remove heat from a cooling fluid circulated through the fluid-cooled plate.

Exemplary methods can further include measuring a temperature of a precursor or one or more assembly components and one or more of (1) controlling current through the thermoelectric cooling device based on the measured temperature, (2) controlling a fan speed of the heat exchanger, and/or (3) controlling a circulation rate of the cooling fluid through the fluid-cooled plate.

In accordance with various aspects of these embodiments, a temperature of the precursor or other component of the precursor vessel cooling assembly can be controlled to a temperature of about 0° C. to about 20° C. below an ambient temperature (e.g., ambient environment 226 and/or 224).

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A precursor vessel cooling assembly comprising:
a precursor vessel;
a thermoelectric cooling device comprising a first surface and a second surface, the first surface in thermal contact with a surface of the precursor vessel; and
a fluid-cooled plate in thermal contact with the second surface, the fluid-cooled plate comprising a conduit and a cooling fluid therein.

2. The precursor vessel cooling assembly of claim 1, further comprising a pump to circulate the cooling fluid through the conduit.

3. The precursor vessel cooling assembly of claim 1, further comprising a heat exchanger and a first cooling fluid line coupled between the fluid-cooled plate and the heat exchanger.

4. The precursor vessel cooling assembly of claim 3, wherein the heat exchanger comprises a fan.

5. The precursor vessel cooling assembly of claim 3, wherein the heat exchanger comprises an outer surface comprising one or more cooling fins.

6. The precursor vessel cooling assembly of claim 3, wherein the heat exchanger comprises a cooling fluid channel.

7. The precursor vessel cooling assembly of claim 1, further comprising a controller.

8. The precursor vessel cooling assembly of claim 7, wherein the controller receives an input corresponding to a temperature of a precursor within the precursor vessel and provides an output to the pump to adjust a flowrate of the cooling fluid.

9. The precursor vessel cooling assembly of claim 7, wherein the controller receives an input corresponding to a temperature of the precursor and provides an output to the thermoelectric cooling device to adjust a current through the thermoelectric cooling device.

10. The precursor vessel cooling assembly of claim 7, wherein the controller receives an input corresponding to a temperature of the precursor and provides an output to control a speed of the fan.

11. The precursor vessel cooling assembly of claim 1, further comprising a housing, wherein the precursor vessel and the thermoelectric cooling device are within the housing, and wherein the heat exchanger is exterior of the housing.

12. The precursor vessel cooling assembly of claim 1, wherein the fluid-cooled plate comprises one or more of copper, aluminum, and stainless steel.

13. A method of cooling a precursor within a precursor vessel, the method comprising:
providing a precursor vessel containing a precursor therein;
cooling the precursor within the precursor vessel using a thermoelectric cooling device comprising a first surface and a second surface, the first surface in thermal contact with a surface of the precursor vessel; and
using a fluid-cooled plate in thermal contact with the second surface, removing heat from the thermoelectric cooling device.

14. The method of claim 13, wherein the step of removing heat comprises circulating a cooling fluid within the fluid-cooled plate.

15. The method of claim 13, further comprising:
measuring a temperature of the precursor; and
controlling current through the thermoelectric cooling device based on the measured temperature.

16. The method of claim 13, further comprising using a heat exchanger to remove heat from a cooling fluid circulated through the fluid-cooled plate.

17. The method of claim 16, further comprising controlling a fan speed of the heat exchanger.

18. The method of claim 13, wherein a temperature of the precursor is controlled to a temperature of about 5° C. to about 10° C. below an ambient temperature.

19. A reactor system comprising:
a reaction chamber;
a precursor delivery system coupled to the reaction chamber, the precursor delivery system comprising at least one precursor vessel cooling assembly comprising:
a precursor vessel;
a thermoelectric cooling device comprising a first surface and a second surface, the first surface in thermal contact with a surface of the precursor vessel;
a fluid-cooled plate in thermal contact with the second surface, the fluid-cooled plate comprising a conduit and a cooling fluid therein;
a pump to circulate the cooling fluid through the conduit;
a heat exchanger; and
a cooling fluid line coupled between the fluid-cooled plate and the heat exchanger.

20. The reactor system of claim 19, further comprising a housing surrounding the precursor vessel cooling assembly and a heat exchanger exterior of the housing.
